(19) United States
(12) Patent Application Publication
(10) Pub. No.: US 2017/0323818 A1
(43) Pub. Date: Nov. 9, 2017

(54) ROTATING AND HOLDING APPARATUS FOR SEMICONDUCTOR SUBSTRATE AND CONVEYING APPARATUS OF ROTATING AND HOLDING APPARATUS FOR SEMICONDUCTOR SUBSTRATE

(71) Applicants: VARIOS CO., LTD., Tatsuno-shi (JP); MICRO SYSTEM CO., LTD., Kawasaki-shi (JP)

(72) Inventor: Gyo YAMAMOTO, Kawasaki-shi (JP)

(21) Appl. No.: 15/382,184

(22) Filed: Dec. 16, 2016

Related U.S. Application Data
(63) Continuation of application No. 13/983,528, filed on Aug. 2, 2013, now abandoned.

(51) Int. Cl. H01L 21/683; H01L 21/687; C23C 16/458

(52) U.S. Cl. CPC H01L 21/683; H01L 21/68792; C23C 16/4584; H01L 21/68764; H01L 21/68771

(57) ABSTRACT

A holding apparatus for a semiconductor substrate and a conveying apparatus for a semiconductor substrate.

A susceptor is fixed to a rotational driving shaft to be attachable and detachable in a vertical direction, the opening portions are formed to extend through the susceptor in a thickness direction of the susceptor, and a meshing portion which meshes with the substrate holders releasably in a vertical direction so that the substrate holder can rotate according to rotation of the susceptor is provided below the susceptor.

### TECHNICAL FIELD

The present invention relates to a rotating and holding apparatus for a semiconductor substrate and a conveying apparatus of a rotating and holding apparatus for a semiconductor substrate, and in particular to a rotating and holding apparatus for a semiconductor substrate and a conveying apparatus of a rotating and holding apparatus for a semiconductor substrate which are used to forma film on a semiconductor substrate in a vapor-phase state by a metalorganic chemical vapor deposition.

### BACKGROUND ART

When a thin film is formed on a surface of a semiconductor substrate, a chemical vapor deposition (CVD) is conventionally used. In the chemical vapor deposition, a thin film is formed by supplying a plurality of vapor-phase materials to a semiconductor substrate element within a reacting furnace to cause reaction at a high temperature.

When a film is formed in a vapor-phase state on a surface of a semiconductor substrate in the reacting furnace by such a metalorganic chemical vapor deposition, a rotating and holding apparatus for a semiconductor substrate is disposed and used within the reacting furnace.

As shown in FIG. 22 and FIG. 23, such a conventional rotating and holding apparatus for a semiconductor substrate 60 has a susceptor 61 formed in a disc shape and rotationally moved, and a plurality of substrate holders 63 formed in a disc shape, attachably and detachably disposed within a plurality of opening portions 62 provided in the susceptor 61 in an opened fashion, formed to rotate within the opening portions 62 according to rotation of the susceptor 61, and having upper faces on which semiconductor substrates are put.

The susceptor 61 is formed in a thin disc shape and is arranged within an opening portion 65 of a ring-like frame portion 64 to be flash with the ring-like frame portion 64. The susceptor 61 is fixed to a rotational shaft portion 66 on a backside of a central portion thereof, and it is rotationally moved within the opening portion 65 according to rotational movement of the rotational shaft portion 66. Teeth 67 provided to project inward of the opening portion 65 are formed on an inner circumferential face portion of the opening portion 65 of the ring-like frame portion 64 over a full circumference thereof along a thickness direction of the ring-like frame portion 64, thereby constituting a spur gear 68.

On the other hand, as shown in FIG. 22, eleven opening portions 62 are provided in the susceptor 61 along a full-circumferential edge direction, and the substrate holders 63 are rotatably and attachably and detachably arranged within the opening portions 62, respectively. Teeth 71 meshing with the teeth 67 are provided on a peripheral edge of the substrate holder 63 to project outward along the thickness direction of the substrate holder 63, thereby constituting a spur gear 69 like the above.

As a result, when the susceptor 61 is rotated according to rotational movement of the rotational shaft portion 66, the substrate holders 63 are rotated within the opening portions 62 due to meshing of the teeth 71 with the teeth 67 of the ring-like frame portion 64, so that the susceptor 61 and the substrate holders 63 form a planetary mechanism.

Then, semiconductor substrates are put on the substrate holders 63 and films are formed on the semiconductor substrates by supplying a plurality of kinds of vapor-phase materials to the semiconductor substrates within a reacting furnace under a predetermined environment to cause reaction at a high temperature.

However, when the films are formed on the surfaces of the semiconductor substrates in a vapor-phase state, if it is assumed that the susceptor 61 having semiconductor substrates which have been put on the respective substrate holders 63 is conveyed, for example, using a robot arm, it is necessary to cause the teeth 69 of all the substrate holders 63 to mesh with the teeth 67 provided on the inner peripheral face portion of the ring-like frame portion 64 along the thickness direction of the ring-like frame portion 64 in a vertical direction in order to convey the susceptor 61 above the ring-like frame portion 64 and dispose the susceptor 61 within the opening portion 65 of the ring-like frame portion 64.

As a result, since it is difficult to cause the teeth 67 of the substrate holders 63 to mesh with the teeth 67 of the ring-like frame portion 64 appropriately and smoothly, it is difficult to convey the susceptor 61 into the reacting furnace using a conveying apparatus having a robot arm.

Therefore, conventionally, after film forming work to the semiconductor substrates within the reacting furnace has been completed, when replacement with next fresh semiconductor substrates is performed, in each case, it is necessary to open the reacting furnace to manually take the semiconductor substrates whose film formations have been completed out of the reacting furnace and dispose the fresh semiconductor substrates on the substrate holders.

As a result, the replacement work of the semiconductor substrates which have been formed with the films is very complicated, which results in such a drawback that production efficiency is not good.

Further, the interior of the reacting furnace constitutes a sealed space of nitrogen, and moisture and oxygen must be essentially removed from the interior, so that when the reacting furnace is opened and work is performed each time replacement with fresh semiconductor substrates is performed like the above, external air is mixed in the nitrogen in the sealed space in each case, which results in such a problem that a sealed space filled with nitrogen must be formed again, thereby causing lowering of working efficiency.

Furthermore, in the conventional rotating and holding apparatus for a semiconductor substrate 60 based upon the planetary mechanism using the spur gears, since the spur gears 69 of the substrate holders 63 must be caused to mesh with the spur gear 68 of the ring-like frame portion 64 properly, the size of the substrate holders 63 must be formed to have a predetermined diameter, so that the diameter of the susceptor 61 reaches the size of a predetermined scale.

As a result, the respective substrate holders 63 disposed in a diametrical direction of the susceptor 61 are spaced largely from each other, so that a large space S is formed at a central portion of the susceptor 61, so that even if a plurality of kinds of vapor-phase materials is supplied in the reacting furnace, vapor-phase materials staying in the space S does not contribute to film formation on the substrates effectively, which results in such a drawback that a supply efficiency of the vapor-phase materials is not good.

Further, a method of supplying gas to groove portions formed on the side of the back faces of the substrate holders and rotate the substrate holders in floating states thereof from the susceptor while also rotationally moving the susceptor, a so-called “gas wheel process” has been proposed conventionally.

However, in such a “gas wheel process”, since a configuration is adopted that while gas is being supplied, the substrate holders are rotationally moved while being caused to float from the susceptor, gas different from the vapor-phase materials for forming films on semiconductor substrates is supplied, so that there is such a problem that flow of the vapor-phase materials for film formation supplied in the vicinities of the substrate holders is blocked and film formation may not be performed sufficiently.

### DISCLOSURE OF THE INVENTION

### Problem to be Solved by the Invention

A problem to be solved by the Invention is to provide a holding apparatus for a semiconductor substrate and a conveying apparatus of a holding apparatus for a semiconductor substrate where, when a film is formed on a semiconductor substrate in a vapor-phase state within a reacting furnace by a metalorganic chemical vapor deposition, a high-quality film can be formed on the semiconductor substrate without using the gas wheel process, and a production efficiency can be improved and a supply efficiency of vapor-phase materials to be supplied to the reacting furnace can be improved because it is unnecessary to open the reacting furnace which has been supplied with the vapor-phase materials to perform manual transfer of a semiconductor substrate into and from the reacting furnace.

### Means for Solving the Problem

In order to solve the above problem, in the invention described in claim 1, there is provided a rotating and holding apparatus for a semiconductor substrate which is used within a reacting furnace in order to form a film on a semiconductor substrate in a vapor-phase state by a metalorganic chemical vapor deposition and which has a susceptor formed in a disc shape to be rotationally moved, a plurality of substrate holders formed in a disc shape, attachably and detachably disposed within a plurality of opening portions provided in the susceptor in an opened fashion and formed to rotate within the opening portions according to rotation of the susceptor, and having upper face portions on which semiconductor substrates are put, and a rotational driving shaft provided below the susceptor and rotating the susceptor, wherein the susceptor is fixed to the rotational driving shaft to be attachable and detachable thereto in a vertical direction, the opening portions are formed to extend through the susceptor in a thickness direction of the susceptor, and a meshing portion with which the substrate holders mesh releasably in the vertical direction to rotate the substrate holders according to rotation of the susceptor is provided below the susceptor.

Therefore, in the rotating and holding apparatus for a semiconductor substrate described in claim 1, since the susceptor is fixed to the rotational driving shaft to be attachable to and detachable from the rotational driving shaft in the vertical direction and the opening portions are formed to extend through the susceptor in the thickness direction of the susceptor, and the engagement portions with which the substrate holders are engaged releasably in the vertical direction so that the substrate holders can be rotated according to rotation of the susceptor is provided below the susceptor, so that a planetary mechanism is constituted of the susceptor, the substrate holders, and the engagement portion, the susceptor can be attached to and detached from the rotational driving shaft in the vertical direction in a state where the susceptor holds the substrate holders.

As a result, by providing a conveying apparatus, the susceptor is conveyed, and it can be detached from the rotational driving shaft to be conveyed and the susceptor can be conveyed to be attached to the rotational driving shaft.

In the invention described in claim 2, the meshing portion is formed in a ring shape as a whole, a plurality of first meshing projections is disposed on an upper face portion of the meshing portion radially at constant intervals along a circumferential direction of the meshing portion and a plurality of second meshing projections which can mesh with the first meshing projections is disposed on a lower face portions of the substrate holders radially along peripheral edge portions of the substrate holders, so that when the substrate holders are disposed within the opening portions, the second meshing projections are disposed so as to project below the opening portions to mesh with the first meshing projections.

In the invention described in claim 2, therefore, the first meshing projections can be caused to mesh with the second meshing projections in the vertical direction, and the meshing can be cancelled in the vertical direction.

In the invention described in claim 3, the first meshing projections are formed of a plurality of slender rectangular parallelepiped portions projecting upward along the thickness direction of the meshing portion and the second meshing projections are formed of a plurality of slender rectangular parallelepiped portions projecting downward along the thickness directions of the substrate holders.

In the invention described in claim 3, therefore, the first meshing projections formed in a slender rectangular parallelepiped shape and the second meshing projections formed in a slender rectangular parallelepiped shape mesh with each other in the vertical direction.

In the invention described in claim 4, a clearance size between adjacent ones of the first meshing projections is formed to be a clearance size larger than a width size of the second meshing projections, and a clearance size between adjacent ones of the second meshing projections is formed to be a clearance size larger than a width size of the first meshing projections, so that the first meshing projections and the second meshing projections mesh with each other with a gap therebetween.

In the invention described in claim 4, therefore, when the susceptor having the substrate holders is fixed to the rotational driving shaft and the second meshing projections formed on the lower faces of the substrate holders are disposed between the first meshing projections formed on the meshing portion, the first meshing projections and the second meshing projections are disposed with a gap therebetween.

In the invention described in claim 5, the opening portions are formed such that diametrical sizes thereof are approximately equal to a radial size of the susceptor, and the opening portions are composed of three opening portions disposed at equal intervals, and the substrate holders are disposed in the opening portions, respectively.

In the invention described in claim 5, therefore, the respective substrate holders are disposed mutually close to one another.

In the invention described in claim 6, a plurality of projection portions are provided at an upper end portion of the rotational driving shaft and a plurality of recessed portions in which the projection portions can be releasably inserted in an engaging fashion in the vertical direction is formed at a central portion of the susceptor.

In the invention described in claim 6, therefore, by causing the plurality of the recessed portions to engage the plurality of projection portions formed at the upper end portion of the rotational driving shaft, the susceptor can be joined to the rotational driving shaft, and the susceptor can be detached from the rotational driving shaft.

In the invention described in claim 7, there is provided a conveying apparatus of a rotating and holding apparatus for a semiconductor substrate which is used for forming a film on a semiconductor substrate in a vapor-phase state by a metalorganic chemical vapor deposition, where a susceptor formed in a disc shape, attachably and detachably engaging a rotational driving shaft disposed below the susceptor, and having substrate holders having semiconductor substrates put on upper faces of the substrate holders and rotatably disposed in a plurality of opening portions provided in an opened fashion is detachably attached to the rotational driving shaft or conveyed out, wherein a conveying arm portion holding the susceptor is provided.

In the invention described in claim 7, by using the conveying arm portion, the susceptor is conveyed to be capable of being attached to and be capable of being detached from the rotational driving shaft.

In the invention described in claim 8, the conveying arm portion is configured to hold a peripheral edge portion of the susceptor. In the invention described in claim 8, therefore, the conveying arm portion can hold the peripheral edge portion of the susceptor to convey the susceptor.

### Advantageous Effect of Invention

In the inventions described in claims 1 and 2, since the susceptor is fixed to the rotational driving shaft to be attachable and detachable in the vertical direction, the opening portions are formed to extend through the susceptor in the thickness direction thereof, and the meshing portion which releasably meshes with the substrate holders in the vertical direction so that the substrate holders can be rotated according to rotation of the susceptor, when films are formed on semiconductor substrates state within a reacting furnace by a metalorganic chemical vapor deposition in the conventional manner, high-quality films can be formed on the semiconductor substrates without using the gas wheel process.

Further, since the susceptor is fixed to the rotational driving shaft so as to be attachable and detachable in the vertical direction and the planetary mechanism where the substrate holders and the meshing portion mesh with the each other in the vertical direction is constituted without using a planetary mechanism using spur gears in the conventional manner, attaching and detaching of the susceptor to and from the rotational driving shaft in the vertical direction are made possible, and the susceptor can be taken out of the reacting furnace using the conveying apparatus in such a state where the semiconductor substrates have been put on the substrate holders without requiring opening the reacting furnace to take the semiconductor substrates which have been formed with films by supplying vapor-phase materials within the reacting furnace out of the reacting furnace and attaching semiconductor substrates to be newly processed to the substrate holders.

Further, since the substrate holders on which semiconductor substrates to be subjected to a process for film formation have been put can be conveyed into the reacting furnace to be installed in the reacting furnace by using a conveying apparatus in such a state that the substrate holders have been disposed on the susceptor, efficiency for conveying of the semiconductor substrates in and out of the reacting furnace can be improved, so that a processing efficiency regarding film formation on semiconductor substrates can be improved.

Furthermore, since it is unnecessary to open the reacting furnace each time the semiconductor substrates whose film formations have been completed are taken out of the reacting furnace, vapor-phase materials supplied to the reacting furnace are not wasted so that a supply efficiency of the vapor-phase materials can be improved.

In the invention described in claim 3, when the susceptor having the substrate holders which have been disposed in the opening portions is joined to the rotational driving shaft in the vertical direction and it is detached from the rotational driving shaft, the first meshing projections and the second meshing projections can be caused to mesh with each other easily, and the meshing between the first meshing projections and the second meshing projections can be released easily.

In the invention described in claim 4, when the susceptor having the substrate holders is fixed to the rotational driving shaft and the meshing projections formed on the lower face portions of the substrate holders are disposed among the meshing projections of the meshing portion, the first meshing projections and the second meshing projections are disposed with gaps formed therebetween, so that since the susceptor and the substrate holders are different in diametrical size, they are different in curvature, which results in difference in arrangement angle between the second meshing projections and the first meshing projection. Therefore, even if each of the second meshing projections is not disposed between adjacent ones of the first meshing projections at an attaching time of the susceptor to the rotational driving shaft, so that it is disposed on one of the first meshing projections, the positions of the first meshing projections are moved due to vibrations or an inertial force according to rotation of the susceptor, so that each of the first meshing projections is disposed between a pair of ones of the first meshing projections and the second meshing projections reliably mesh with the first meshing projections.

In the invention described in claim 5, since the substrate holders are provided along the circumferential direction of the susceptor at equal intervals by three, and formation is made such that the diametrical size of the substrate holders is approximately equal to the radial size of the susceptor, the substrate holders occupy most part of the susceptor, so that a large space portion is not formed between the respective substrate holders at a central portion of the susceptor, which is different from the case where the planetary mechanism is constituted of spur gears in the conventional manner.

As a result, when a plurality of kinds of vapor-phase materials is supplied into the reacting furnace, such a situation that the vapor-phase materials do not contribute to film formation on the semiconductor substrates due to staying of the vapor-phase materials in the space portion can be prevented, so that the vapor-phase materials are not wasted and a supply efficiency of the vapor-phase materials can be improved.

In the invention described in claim 6, by causing the plurality of recessed portions to engage the plurality of projection portion formed at the upper end portion of the rotational driving shaft, the susceptor can be joined to the rotational driving shaft and the susceptor can be detached from the rotational driving shaft, so that the susceptor can be easily attached to and detached from the rotational driving shaft.

In the inventions described in claims 7 and 8, since using the conveying arm portion, the susceptor is conveyed to be attachable to the rotational driving shaft and detachable from the rotational driving shaft, it is unnecessary to open the reacting furnace to manually take the semiconductor substrates which have been formed with films by supplying vapor-phase materials within the reacting furnace out of the reacting furnace and manually attach semiconductor substrates to be newly processed to the substrate holders to dispose the substrate holders to the susceptor in the conventional manner, and since by using the conveying apparatus, the susceptor including the substrate holders having semiconductor substrates which have been put thereon can be taken out of the reacting furnace regarding the semiconductor substrate whose film forming process has been completed and setting of semiconductor substrates to be subjected to film forming process into the reacting furnace can be performed, an efficiency for conveying of the semiconductor substrates into and out of the reacting furnace can be improved, so that a processing efficiency regarding film formation on a semiconductor substrate can be improved.

### BRIEF DESCRIPTION OF THE DRAWINGS

FIG. 1 is a conceptual diagram showing an embodiment of a rotating and holding apparatus for a semiconductor substrate according to the present invention in a plan view aspect;

FIG. 2 is a sectional view showing the embodiment of the rotating and holding apparatus for a semiconductor substrate according to the present invention and corresponding to a line 2-2 in FIG. 1;

FIG. 3 is a cross-sectional view showing the embodiment of the rotating and holding apparatus for a semiconductor substrate according to the present invention and showing a substrate holder slip ring;

FIG. 4 is a plan view showing the embodiment of the rotating and holding apparatus for a semiconductor substrate according to the present invention and showing a susceptor main body;

FIG. 5 is a sectional view showing the embodiment of the rotating and holding apparatus for a semiconductor substrate according to the present invention and corresponding to line 5-5 in FIG. 4;

FIG. 6 is a back view showing the embodiment of the rotating and holding apparatus for a semiconductor substrate according to the present invention and showing the susceptor main body;

FIG. 7 is a sectional view showing the embodiment of the rotating and holding apparatus for a semiconductor substrate according to the present invention, corresponding to line 2-2 in FIG. 1, and showing an arrangement state of heaters;

FIG. 8 is a plan view showing the embodiment of the rotating and holding apparatus for a semiconductor substrate according to the present invention and showing a meshing portion;

FIG. 9 is a sectional view showing the embodiment of the rotating and holding apparatus for a semiconductor substrate according to the present invention and corresponding to line 9-9 in FIG. 8;

FIG. 10 is a cross-sectional view showing the embodiment of the rotating and holding apparatus for a semiconductor substrate according to the present invention and showing a susceptor slip ring;

FIG. 11 is a plan view showing the embodiment of the rotating and holding apparatus for a semiconductor substrate according to the present invention and showing a substrate holder;

FIG. 12 is a sectional view showing the embodiment of the rotating and holding apparatus for a semiconductor substrate according to the present invention and corresponding to line C-C in FIG. 11;

FIG. 13 is a back view showing the embodiment of the rotating and holding apparatus for a semiconductor substrate according to the present invention and showing the substrate holder;

FIG. 14 is a conceptual sectional view showing an embodiment of a rotating and holding apparatus for a semiconductor substrate and a conveying apparatus thereof according to the present invention, showing a case where the susceptor is conveyed to be attached to a rotational driving shaft using a conveying apparatus, and corresponding to line 2-2;

FIG. 15 is a conceptual sectional view showing the embodiment of the rotating and holding apparatus for a semiconductor substrate and the conveying apparatus thereof according to the present invention and showing a state where the susceptor is conveyed to be attached to the rotational driving shaft using the conveying apparatus, where complete meshing of a meshing projection portion is not achieved and the susceptor has been slightly inclined;

FIG. 16 is a conceptual sectional view showing the embodiment of the rotating and holding apparatus for a semiconductor substrate and the conveying apparatus thereof according to the present invention and showing a state where the susceptor is conveyed to be attached to the rotational driving shaft using the conveying apparatus, where complete meshing of the meshing projection portion is not achieved and the susceptor is rotating in an inclined state thereof;

FIG. 17 is a conceptual sectional view showing the embodiment of the rotating and holding apparatus for a semiconductor substrate and the conveying apparatus thereof according to the present invention and showing a state where the susceptor is conveyed to be attached to the rotational driving shaft using the conveying apparatus, where meshing of the meshing projection portion is achieved and the susceptor is rotating in a horizontal state;

FIG. 18 is a sectional view of an embodiment of a rotating and holding apparatus for a semiconductor substrate and a conveying apparatus thereof according to the present invention and corresponding to the line 2-2;

FIG. 19 is a conceptual sectional view showing the embodiment of a rotating holding apparatus for a semiconductor substrate and a conveying apparatus thereof according to the present invention and showing a case where the susceptor is conveyed using the conveying apparatus and semiconductor substrate replacement is performed, where the susceptor has been lifted up by a conveying arm portion;

FIG. 20 is a conceptual sectional view showing the embodiment of a rotating holding apparatus for a semiconductor substrate and a conveying apparatus thereof according to the present invention and showing a case where the susceptor is conveyed using the conveying apparatus and semiconductor substrate replacement is performed, where the susceptor has been lifted up by a conveying arm portion;

FIG. 21 is a conceptual sectional view showing the embodiment of a rotating holding apparatus for a semiconductor substrate and a conveying apparatus thereof according to the present invention and showing a case where the susceptor is conveyed using the conveying apparatus and semiconductor substrate replacement is performed, where detachment of the susceptor has been completed;

FIG. 22 is a plan view showing an example of a conventional rotating and holding apparatus for a semiconductor substrate and a conveying apparatus thereof; and

FIG. 23 is a sectional view showing the example of the conventional rotating and holding apparatus for a semiconductor substrate and the conveying apparatus thereof, and corresponding to line D-D in FIG. 22.

### BEST MODE FOR CARRYING OUT THE INVENTION

The present invention will be described in detail below based upon embodiments shown in accompanying drawings.

[Overall Configuration]

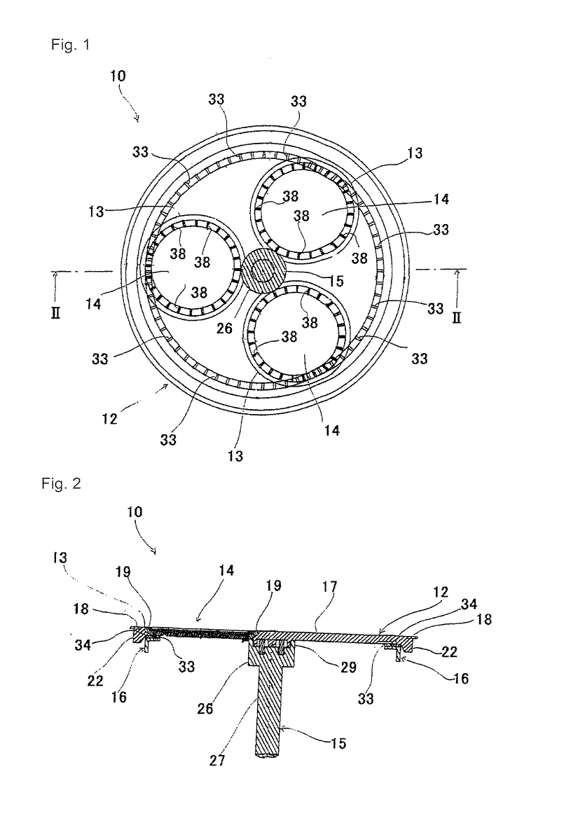

As shown in FIG. 1 and FIG. 2, a rotating and holding apparatus for a semiconductor substrate 10 according to an embodiment is used in a reacting furnace for forming a film on a semiconductor substrate in a vapor-phase state by a metalorganic chemical vapor deposition and has a susceptor 12 formed in a disc shape to be rotationally moved, a plurality of substrate holders 14 formed in a disc shape, attachably and detachably disposed within three opening portions 13 provided in the susceptor 12 in an opened fashion and formed to be rotated within the opening portions 13 according to rotation of the susceptor 12, and having upper faces on which semiconductor substrates are put, and a rotational driving shaft 15 provided below the susceptor 12 and rotating the susceptor 12.

The susceptor 12 is fixed to the rotational driving shaft 15 to be attachable and detachable in a vertical direction and the opening portions 13 are formed to extend through the susceptor 12 in a thickness direction of the susceptor 12, and a meshing portion 16 releasably meshing with the substrate holders 14 in the vertical direction and allowing rotations of the substrate holders 14 according to rotation of the susceptor 12.

[Susceptor]

As shown in FIG. 1 and FIG. 2, the susceptor 12 is composed of a thin disc-shaped susceptor main body 17 and a susceptor ring 18 fixed to a peripheral upper edge portion of the susceptor main body 17 over a whole circumference thereof.

In this embodiment, as shown in FIG. 4 and FIG. 5, the susceptor 12 is formed to have a diameter of 145 mm, the opening portions 13 have a diametrical size of 55.2 mm, and a radius L between the center of the susceptor 12 and the center of each opening portion 13 is 37 mm, the opening portions 13 are provided by three at equal intervals in an opening fashion, and the substrate holders 14 are disposed in the opening portions 13, respectively. In this embodiment, the opening portions 13 are disposed at angular positions of 120° from one another.

As shown in FIG. 5, the opening portion 13 is opened to extend through the susceptor main body 17 along a thickness direction of the susceptor main body 17 and a sectional configuration thereof is formed in such a taper shape that a diameter thereof is reduced toward a back face of the susceptor.

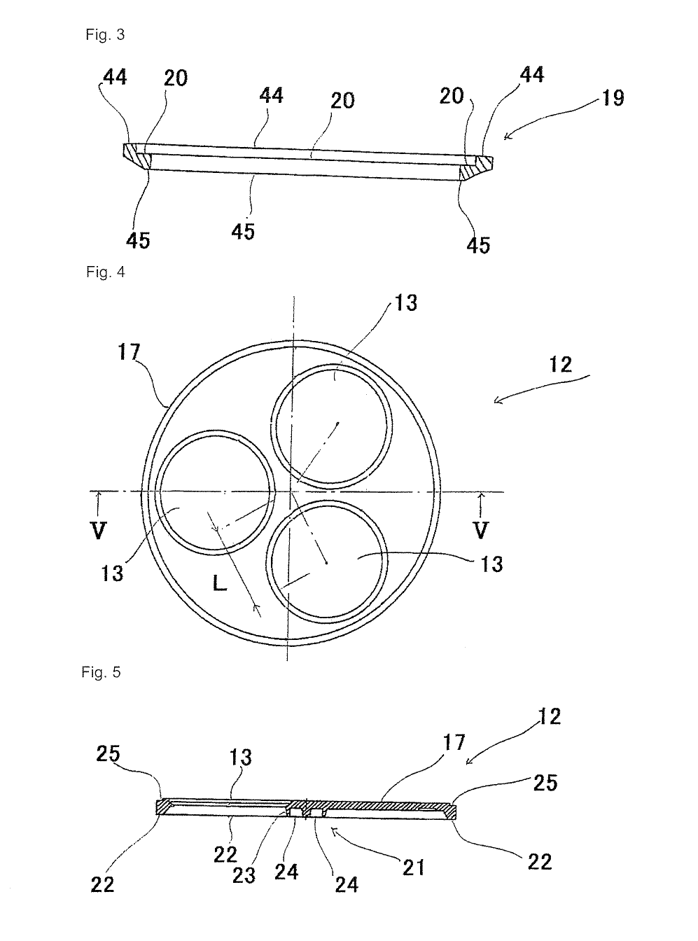

In the opening portion 13, a substrate holder slip ring 19 shown in FIG. 3 is disposed. The substrate holder slip ring 19 is made of glass-like carbon, is formed in an approximately-ring-like shape in plan view, and is configured to be capable of rotatably receiving the substrate holder 14 therein.

As shown in FIG. 3, the substrate holder slip ring 19 has an outer sectional contour shape equal to a sectional shape of the opening portion 3, and it has an inner peripheral portion formed with a stepped portion 20.

[Susceptor •Joining Portion]

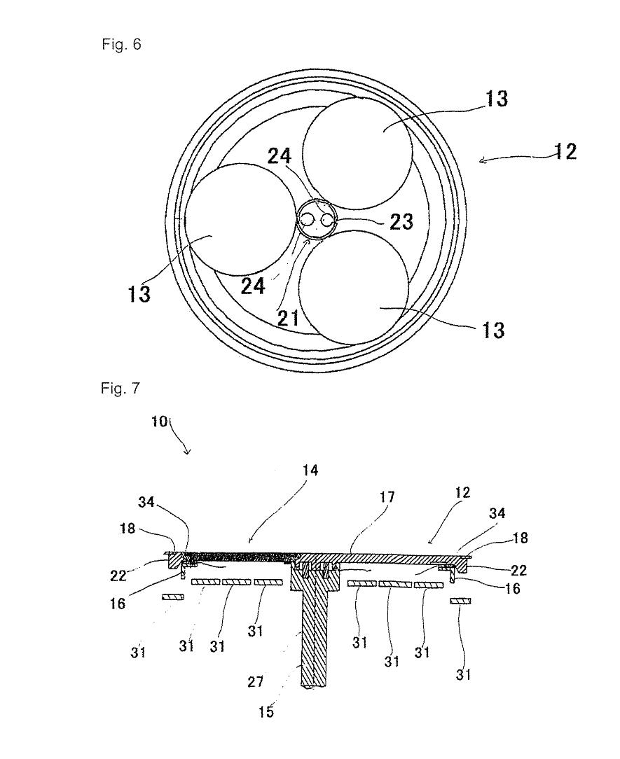

As shown in FIG. 4 to FIG. 6, the susceptor main body 17 has a joining portion 21 with the rotational driving shaft 15 provided at a central portion thereof on a back face side thereof in a projecting fashion and a peripheral edge projection portion 22 formed at a peripheral edge lower portion thereof.

The joining portion 21 is composed of a short cylindrical bulging portion 23 formed below the susceptor 12 and two recessed portions 24 and 24 formed within the budging portion 23 and opened in the back face direction. The pair of recessed portions 24 and 24 is formed in a diametrical direction in a paired fashion. Further, a peripheral edge of a surface portion of the susceptor is formed with a stepped portion 25 to which the susceptor ring 18 shown in FIG. 2 is fixed.

[Susceptor •Rotational Shaft Portion]

As shown in FIG. 2, the rotational driving shaft 15 is formed in a slender column shape as a whole, and it is joined to a proper rotational driving portion to be disposed within the reacting furnace.

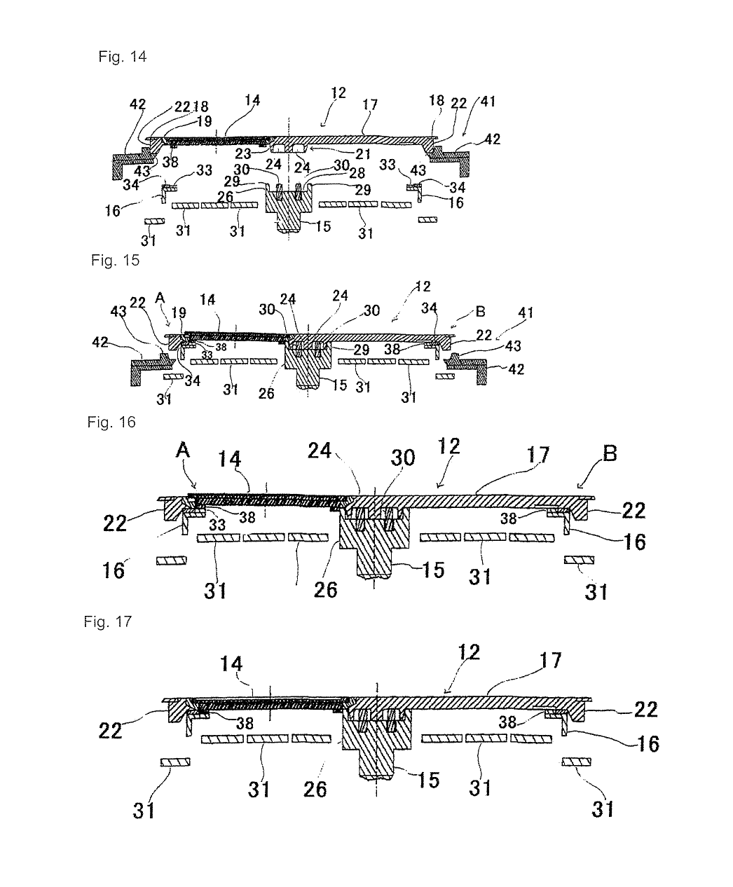

A joining receiving portion 26 for the susceptor 12 is formed at an upper end portion of the rotational driving shaft 15. As shown in FIG. 14 and FIG. 21, the joining receiving portion 26 is formed to have a diameter larger than the diameter of a rotational driving shaft main body portion 27, and it is composed of an annular holding portion 29 provided to project from a peripheral edge portion of a joining upper end face portion 28 upward and holding the bulging portion from the outside of the bulging portion and two projection portions 30 and 30 provided within the annular holding portion 29 so as to project upward and arranged within the two recessed portions in an engaging fashion.

Therefore, when the susceptor 12 is joined to the rotational driving shaft 15, the two projection portions 30 and 30 are arranged within the two recessed portions 24 and 24 in an engaging fashion, so that rotational driving force of the rotational driving shaft 15 is transmitted to the susceptor 12 to rotate the susceptor 12.

Further, as shown in FIG. 7, a plurality of heaters 31 is arranged around the rotational driving shaft 15 over a whole area in a diametrical direction of the susceptor 12 so as to heat the susceptor 12 from below.

[Meshing Portion]

As shown in FIG. 2, FIG. 7, FIG. 14, FIG. 20 or FIG. 21, a meshing portion 16 meshing with the substrate holders 14 to rotate the substrate holders 14 when the susceptor 12 is joined to the rotational driving shaft 15 is disposed below a peripheral edge portion of the susceptor 12.

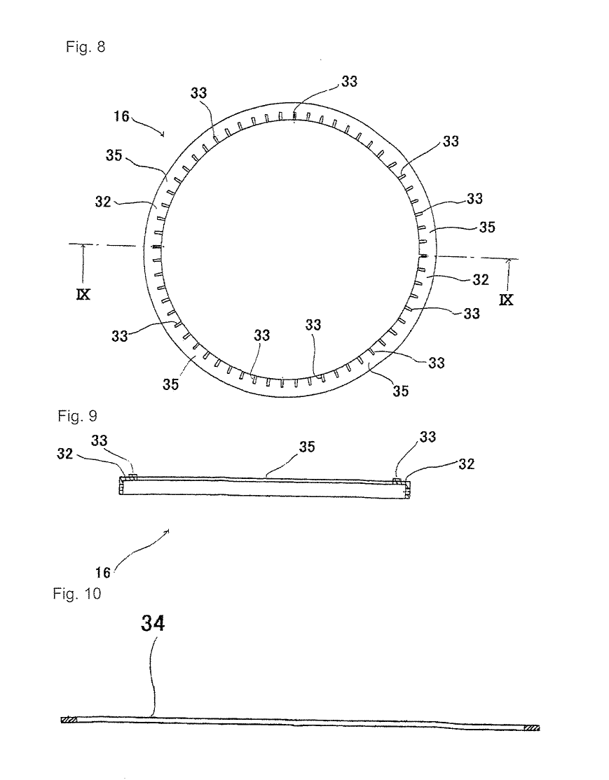

As shown in FIG. 8 and FIG. 9, the meshing portion 16 is formed in an approximately-ring-like shape as a whole to have an outer diameter of 132.6 mm and an inner diameter of 117 mm. The meshing portion 16 is composed of a susceptor-putting portion 32 formed in an inversed L shape in lateral section, a number of first meshing projections 33 formed on an upper face of the susceptor-putting portion 32 radially, and an annular susceptor slip ring 34 disposed on the susceptor-putting portion 32 outside in lengthwise directions of the meshing projections 33 and shown in FIG. 10.

The first meshing projections 33 are composed of a plurality of slender rectangular parallelepiped portions projecting upward along a thickness direction of the meshing portion 16, they are formed to have a length size of 3.5 mm, a width size of 1 mm, and a height size of 1.3 mm, and the number thereof is 60 as a whole in this embodiment.

The first meshing projections 33 are formed on an inner half of the upper face portion 35 of the meshing portion 16 in a widthwise direction of the meshing portion 16, and the susceptor slip ring 34 shown in FIG. 10 is fixed on the susceptor-putting portion 32 in an outer half of the upper face portion 35 in the widthwise direction.

The susceptor slip ring 34 is formed in a flat ring shape and when the susceptor slip ring 34 is disposed on the susceptor-putting portion 32, it abuts on the peripheral edge lower face portion of the susceptor main body 17 so that susceptor 12 is rotated smoothly.

[Substrate Holder]

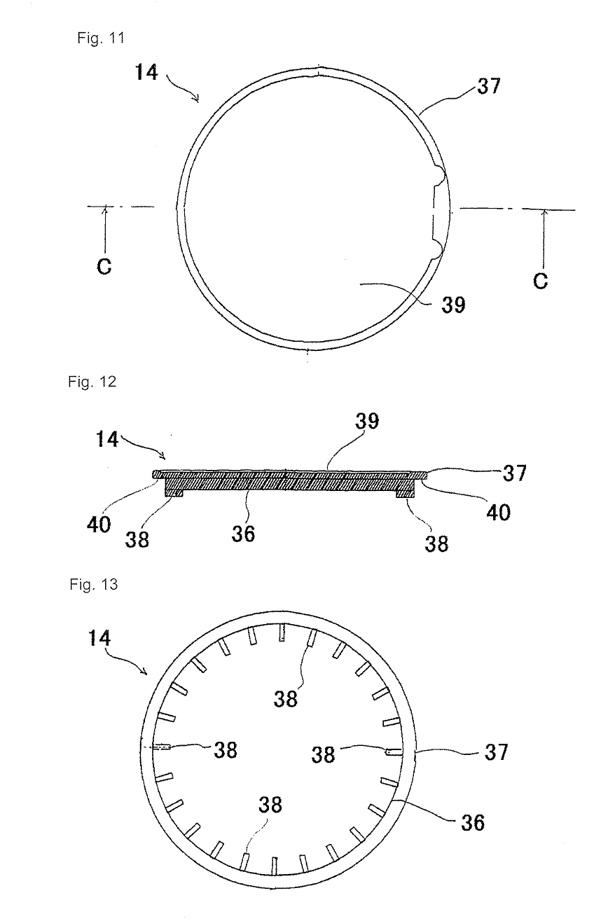

As shown in FIG. 11 to FIG. 13, the substrate holder 14 disposed in the opening portion 13 is formed in a small-sized thin disc shape, and it is composed of a substrate holder main body 36 and a substrate-putting portion 37 formed at an upper portion of the substrate holder main body 36 to be larger in diameter than the substrate holder main body 36.

A number of second meshing projections 38 capable of meshing with the first meshing projections 33 formed on the susceptor-putting portion 37 are radially formed on a peripheral edge of a lower face portion of the substrate holder main body 36. Further, a recessed portion 39 on which a substrate is to be put is formed approximately over a whole region of an upper face portion of the substrate-putting portion 37.

A thickness size of the substrate-putting portion 37 is formed to have the same size as a distance size between a surface of the stepped portion 20 of the substrate holder slip ring 19 shown in FIG. 3 and a surface 44 of the substrate holder slip ring 19, and a thickness size of the substrate holder main body 36 is formed to have the same size as a distance size between the surface of the above-described stepped portion and a back face 45 of the substrate holder slip ring 19.

Therefore, when the substrate holder 14 is received in the substrate holder slip ring 19 fixed to the opening portion 13 of the susceptor 12, a surface portion of the substrate-putting portion 37 is disposed to be flash with the surface 44 of the substrate holder slip ring 19, and the second meshing projections 38 are disposed to project below the back face 45 of the substrate holder slip ring 19 to be capable of meshing with the first meshing projections 33.

The second meshing projections 38 are formed to have a length size of 3.5 mm, a width size of 1 mm, and a height size of 1.3 mm in the same manner as the first meshing projections 33, and in this embodiment, 24 second meshing projections 38 are radially arranged by 24 as a whole.

In this embodiment, the substrate holder 14 is made of SiC (silicon carbide), and the recessed portion 39 is formed to have a size in which a sheet of 2-inch substrate can be fitted.

As shown in FIG. 1, three substrate holders 14 are arranged along a circumferential direction of the susceptor 12 at equal intervals, and a diametrical size of the substrate holder 14 is formed to be approximately equal to a distance size between the peripheral edge projection portion 22 of the susceptor 12 and the joining portion 21.

A distance size between the first meshing projections 33 and 33 adjacent to each other is formed to have a distance size larger than the width size of the second meshing projections 38, and a distance size between the second meshing projections 38 and 38 adjacent to each other is formed to be larger than a width size of the first meshing projections 33.

As a result, the first meshing projections 33 and the second meshing projections 38 mesh with each other with a clearance formed therebetween.

[Conveying Apparatus]

Further, as shown in FIG. 14 and FIG. 15, a susceptor conveying apparatus 41 is provided with a pair of conveying arm portions 42 and 42 for holding the susceptor 12. The conveying arm portions 42 and 42 is configured to hold the peripheral edge projection portion 22 of the susceptor 12, and they are provided with approximately-L-shaped supporting portions 43 in inside sectional shape so as to be capable of supporting the peripheral edge projection portion 22 from below.

In this embodiment, the conveying arm portions 42 and 42 are configured to be arranged in a paired manner in a diametrical direction of the susceptor 12 at a conveying time of the susceptor 12.

The susceptor conveying apparatus 41 is provided with an actuator with a proper configuration (not shown), the conveying arm portions 42 and 42 driven by the actuator, and a sensor with a proper configuration feeding a detection signal of the actuator so as to be capable of performing such movement control that the conveying arm portions 42 and 42 grasp the peripheral edge projection portion 22 of the susceptor, and it is configured so as to be capable of grasping the susceptor 12 placed outside the reacting furnace to convey the same into the reacting furnace and join the susceptor 12 to the rotational driving shaft 15 and cause the susceptor 12 to engage the meshing portion 16, and detaching the susceptor 12 from the rotational driving shaft 15 to convey the susceptor 12 outside the reacting furnace.

[Operation]

A case where the rotating and holding apparatus for a semiconductor substrate according to this embodiment is used to form a film on a semiconductor substrate in a vapor-phase state by a metalorganic chemical vapor deposition will be described below.

First of all, the substrate holder slip rings 19, 19, and 19 shown in FIG. 3 are fitted into the three opening portions 13, 13, and 13 of the susceptor 12, respectively. Thereafter, as shown in FIG. 1 and FIG. 2, the respective substrate holders 14 are fixed on the substrate slip rings 19 to the respective opening portions 13, 13, and 13.

In this case, the peripheral edge lower portion 40 of the substrate-putting portion 37 of the substrate holder 14 is engaged with the stepped portion 20 of the substrate holder slip ring 19 to be disposed rotatably. Further, the 2-inch semiconductor substrate is fixed to the recessed portion 39 of the substrate holder-putting portion 37 formed on the upper portion of the substrate holder 14 in an engaging fashion.

Thereafter, the susceptor 12 is conveyed into the reacting furnace using the susceptor conveying apparatus 41. As shown in FIG. 14, in the susceptor conveying apparatus 41, the conveying arm portions 42 and 42 are driven by the actuator (not shown) and the peripheral edge projection portion 22 of the susceptor 12 is held by the conveying arm portions 42 and 42, the joining portion 21 formed on the back face portion of the susceptor 12 is conveyed up to a position just above the rotational driving shaft 15 disposed within the reacting furnace, thereafter, the conveying arm portions 42 and 42 are lowered by the actuator, the bulging portion 23 of the joining portion 21 is grasped by the annular holding portion 29 of the joining receiving portion 26, and the pair of projection portions 30 and 30 of the rotational driving shaft 15 is inserted and disposed in the pair of recessed portions 24 and 24 of the joining portion 21. Thereby, the susceptor 12 is joined to the rotational driving shaft 15 via the joining portion 21 and the joining receiving portion 26 so that a rotational driving force of the rotational driving shaft 15 is transmitted to the susceptor 12.

Further, the susceptor main body portion 17 is put on the meshing portion 16 via the susceptor slip ring 34 and the second meshing projections 38 of the substrate holder 14 are disposed between adjacent the first meshing projections 33 formed on the meshing portion 16, respectively.

In this state, when the rotational driving shaft 15 starts to rotate by a rotational driving force from the rotational driving shaft, for example, at a rate of two rotations per minute, the susceptor 12 starts to rotate on the susceptor slip ring 34 of the meshing portion 16 at a rate of two rotations per minute. In this case, since the second meshing projection portions 38 of three substrate holders 17 mesh with the first meshing projections 33 of the meshing portion 16, the three substrate holders 17 also start to rotate within the opening portions 13 according to rotation of the susceptor 12.

Incidentally, when the joining portion 21 of the susceptor 12 is joined to the joining receiving portion 26, such a case may occur that the second meshing projections 38 of any one of the three substrate holders 17 are disposed to overlap with the first meshing projections 33.

When the second meshing projections 38 are disposed to overlap with the first meshing projections 33 in this manner, as shown in FIG. 15, an end portion A of the susceptor 12 on the overlapping arrangement side of the susceptor 12 becomes slightly high on the meshing portion 16 and an end portion B of the susceptor 12 where the second meshing projections 38 are disposed between the first meshing projections 33 becomes low, so that the susceptor 12 is disposed on the meshing portion 16 in a slightly inclined fashion along a diametrical direction. In this embodiment, a height of the end portion A obliquely lifted up in the inclined fashion is 1.1 mm.

In this state, when the rotational driving shaft 15 starts to rotate by the rotational driving force from the rotational driving portion, for example, at a rate of two rotations per minute, the susceptor 12 starts to rotate on the susceptor slip ring 34 on the meshing portion 16 at a rate of two rotations per minute. In this case, since the second meshing projections 38 of any of the three substrate holders 17 mesh with the first meshing projections 33 of the meshing portion 16, even if the second meshing projections 38 are disposed to overlap with the first meshing projections 33, the first meshing projections 33 disposed on the second meshing projections 38 drop from the second meshing projections 38 to mesh with the second meshing projections 38 due to inertia or vibrations according to rotation of the susceptor 21, as shown in FIG. 17.

In this embodiment, since the distance size between the first meshing projections 33 and 33 adjacent to each other is formed to have a distance size larger than the width size of the second meshing projection 38 and the distance size between the second meshing projections 38 and 38 adjacent to each other is formed to have a distance size larger than the width size of the first meshing projection 33, the first meshing projections 33 and the second meshing projections 38 mesh with each other in a loosely fitted state formed therebetween, so that even if any of the first meshing projections 33 is put on the second meshing projections 38, a meshing state can be secured easily according to rotation of the susceptor 12, as described above.

Thereafter, rotation of the rotational driving shaft 15 is increased up to 10 rotations per minute, so that while each substrate holder 14 revolves on the susceptor 12 at a rate of 10 rotations per minute, it simultaneously rotates within the opening portion 13 at a rate of 25 rotations per minute.

For example, according to a metalorganic chemical vapor deposition, mixed gas of hydrogen gas, ammonia gas, and trimethyl gallium (TMG) is supplied into the sealed reacting furnace and crystals of gallium nitride are caused to grow on semiconductor substrates disposed on the three substrate holders 14 under a temperature condition of 1100° C.

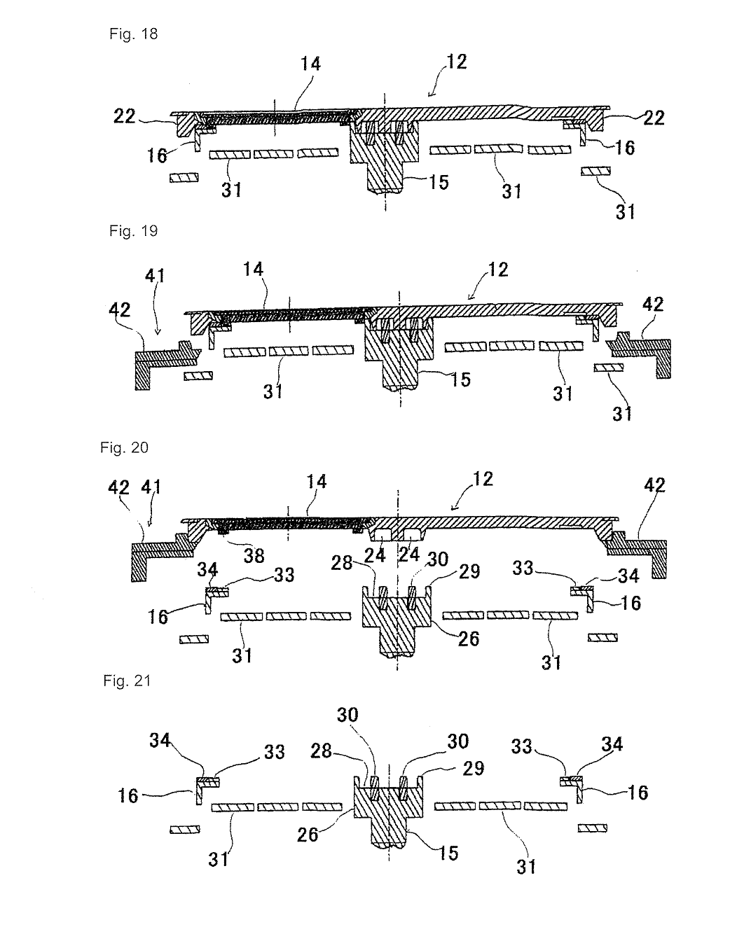

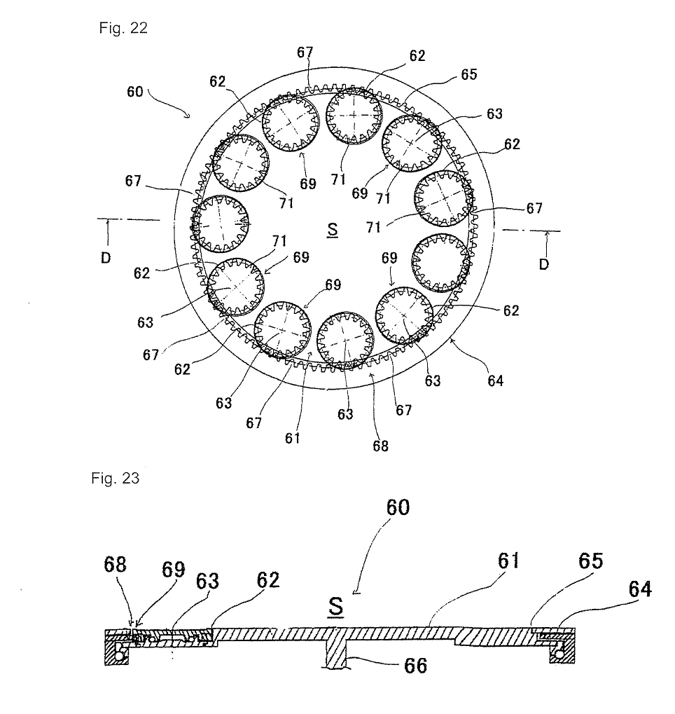

When crystals of gallium nitride are formed on the semiconductor substrates in a film state in this manner, as shown in FIG. 18 to FIG. 21, after the rotation of the rotational driving shaft 15 is stopped, the conveying arm portions 42 and 42 are caused to come close to the susceptor 12 from below the peripheral edge projection portion 22 by driving the conveying arm portions 42 and 42 by the susceptor conveying apparatus 41 and the peripheral edge projection portion 22 is supported from below by the supporting portions 43 of the conveying arm portions 42 to lift up the susceptor 12 upward and convey the susceptor 12 out of the reacting furnace according to a procedure reversed to the above procedure.

### Advantageous Effect of Embodiment

In this embodiment, therefore, as described above, since the susceptor 12 is fixed to the rotational driving shaft 15 to be attachable and detachable in the vertical direction and the planetary mechanism where the second meshing projections 38 formed on the lower face of the substrate holders 14 and the first meshing projections 33 formed on the upper face of the meshing portion 16 mesh with each other in the vertical direction is constituted without using the planetary mechanism using spur gears like the conventional manner, attaching and detaching of the susceptor 12 to and from the rotational driving shaft 15 in the vertical direction can be made easy.

As a result, it becomes unnecessary to open the reacting furnace to manually take the semiconductor substrates having a film which has been formed within the reacting furnace by supplying vapor-phase materials into the reacting furnace out of the reacting furnace and attach semiconductor substrates to be newly processed to the substrate holders 14 on the susceptor 12 within the reacting furnace, which is different from the conventional technique, the susceptor 12 having the semiconductor substrates which have been put on the substrate holders 14 can be taken out of the reacting furnace using the susceptor conveying apparatus 41, and the substrate holders 14 which have semiconductor substrates to be newly subjected to film formation process and which have been disposed on the susceptor 12 can be conveyed and set within the reacting furnace using the susceptor conveying apparatus 41.

Further, since, while the semiconductor substrates which have been put on the substrate holders 14 are rotating on the substrate holders 14, they are revolved on the susceptor 12 by the planetary mechanism, a temperature distribution acting on the respective semiconductor substrates can be made even within the reacting furnace, and a film pressure distribution to be formed can be made even.

Further, in this embodiment, since the planetary mechanism is constituted according to meshing of the meshing projections 33 and 38 with each other in the thickness direction of the susceptor 12, which is different from the planetary mechanism utilizing spur gears like the conventional art, the diameter of the susceptor 12 can be reduced, which is different from the rotating and holding apparatus for a semiconductor substrate utilizing the conventional planetary mechanism using spur gears.

As a result, since the opening portions 13 in which the substrate holders 14 are put are formed such that their diametrical sizes are approximately equal to the radial size of the susceptor 12, they are provided at equal intervals by three in an opened fashion, and the substrate holders 14 are disposed in the opening portions 13, respectively, a large space are not formed at a central portion of the susceptor between the respective substrate holders, which is different from the case where the planetary mechanism is constituted of spur gears in the conventional manner.

As a result, when a plurality of kinds of vapor-phase materials is supplied into the reacting furnace, such a situation that the vapor-phase materials do not contribute to film formation on the semiconductor substrates due to staying of the vapor-phase materials in the space portion can be prevented, so that the vapor-phase materials are not wasted and a supply efficiency of the vapor-phase materials can be improved.

### INDUSTRIAL APPLICABILITY

The present invention can be widely applied to a semiconductor manufacturing apparatus for forming a film on a semiconductor substrate in a metalorganic chemical vapor deposition and a conveying apparatus of a rotating and holding apparatus for a semiconductor substrate.

### EXPLANATION OF REFERENCE NUMERALS

10 rotating and holding apparatus for a semiconductor substrate
12 susceptor
13 opening portion
14 substrate holder
15 rotational driving shaft
16 meshing portion
17 susceptor main body
18 susceptor ring
19 substrate holder slip ring
20 stepped portion
21 joining portion
22 peripheral edge projection portion
23 bulging portion
24 recessed portion
25 stepped portion
26 joining receiving portion
27 rotational driving shaft main body
28 joining upper end face portion
29 annular holding portion
30 projection portion
31 heater
32 susceptor-putting portion
33 first meshing projection
34 susceptor slip ring
35 upper face portion
36 substrate holder main body
37 substrate-putting portion
38 second meshing portion
39 recessed portion
40 peripheral edge lower portion
41 susceptor conveying apparatus
42 conveying arm portion
43 supporting portion
44 surface
45 back face
60 rotating and holding apparatus for a semiconductor substrate
61 susceptor
62 opening portion
63 substrate holder
64 ring-like frame portion
65 opening portion
66 rotational shaft portion
67 teeth
68 spur gear
69 spur gear
71 teeth

What is claimed is:

1. A rotating and holding apparatus for a semiconductor substrate which is used within a reacting furnace in order to form a film on a semiconductor substrate in a vapor-phase state by a metalorganic chemical vapor deposition and which has a susceptor formed in a disc shape to be rotationally moved, a plurality of substrate holders formed in a disc shape, attachably and detachably disposed within a plurality of opening portions provided in the susceptor in an opened fashion and formed to rotate within the opening portions according to rotation of the susceptor, and having upper face portions on which semiconductor substrates are put, and a rotational driving shaft provided below the susceptor and rotating the susceptor,
wherein the susceptor is fixed to the rotational driving shaft to be attachable and detachable thereto in a vertical direction, the opening portions are formed to extend through the susceptor in a thickness direction of the susceptor, and
a meshing portion with which the substrate holders mesh releasably in the vertical direction to rotate the substrate holders within the opening portions according to rotation of the susceptor is provided below the susceptor.

2. The rotating and holding apparatus for a semiconductor substrate according to claim 1, wherein the meshing portion is formed in a ring shape as a whole, a plurality of first meshing projections is disposed on an upper face portion of the meshing portion radially at constant intervals along a circumferential direction of the meshing portion and a plurality of second meshing projections which can mesh with the first meshing projections is disposed on a lower face portions of the substrate holders radially along peripheral edge portions of the substrate holders, so that when the substrate holders are disposed within the opening portions, the second meshing projections are disposed so as to project below the opening portions to mesh with the first meshing projections.

3. The rotating and holding apparatus for a semiconductor substrate according to claim 2, wherein the first meshing projections are formed of a plurality of slender rectangular parallelepiped portions projecting upward along the thickness direction of the meshing portion and the second meshing projections are formed of a plurality of slender rectangular parallelepiped portions projecting downward along the thickness directions of the substrate holders.

4. The rotating and holding apparatus for a semiconductor substrate according to claim 3, wherein a clearance size between adjacent ones of the first meshing projections is formed to be a clearance size larger than a width size of the second meshing projections, and a clearance size between adjacent ones of the second meshing projections is formed to be a clearance size larger than a width size of the first meshing projections, so that the first meshing projections and the second meshing projections mesh with each other with a gap therebetween.

5. The rotating and holding apparatus for a semiconductor substrate according to claim 2, wherein the opening portions are formed such that diametrical sizes thereof are approximately equal to a radial size of the susceptor, and the opening portions are composed of three opening portions disposed at equal intervals, and the substrate holders are disposed in the opening portions, respectively.

6. The conveying apparatus of the rotating and holding apparatus for a semiconductor substrate according to claim 5, wherein a plurality of projection portions are provided at an upper end portion of the rotational driving shaft and a plurality of recessed portions in which the projection portions can be releasably inserted in an engaging fashion in the vertical direction is formed at a central portion of the susceptor.

7. A conveying apparatus of a rotating and holding apparatus for a semiconductor substrate, which is used for forming a film on a semiconductor substrate in a vapor-phase state by a metalorganic chemical vapor deposition,
where a susceptor formed in a disc shape, attachably and detachably engaging a rotational driving shaft disposed below the susceptor, and having substrate holders having semiconductor substrates put on upper faces of the substrate holders and rotatably disposed in a plurality of opening portions provided in an opened fashion is detachably attached to the rotational driving shaft or conveyed out, wherein a conveying arm portion holding the susceptor is provided.

8. The conveying apparatus of a rotating and holding apparatus for a semiconductor substrate according to claim 7, wherein the conveying arm portion is configured to hold a peripheral edge portion of the susceptor.
